(19) United States
(12) Patent Application Publication
(10) Pub. No.: US 2016/0309621 A1
(43) Pub. Date: Oct. 20, 2016

(54) RACK HAVING FAN SPEED COMPENSATING FUNCTION AND COMPENSATING METHOD FOR THE SERVER RACK

(71) Applicant: AIC INC., Taoyuan Hsien (TW)

(72) Inventors: Yen-Yu CHEN, Taoyuan Hsien (TW); Wan-Chun YEH, Taoyuan Hsien (TW); Yu-Heng SU, Taoyuan Hsien (TW); Shih-Chieh HSU, Taoyuan Hsien (TW)

(21) Appl. No.: 14/688,243

(22) Filed: Apr. 16, 2015

(51) Int. Cl. H05K 7/20

(52) U.S. Cl. CPC H05K 7/20836; H05K 7/20736

(57) ABSTRACT

A rack having a plurality of fans and a plurality of servers divided into several groups is presented. Each of the servers calculates fan speed needed for heat dissipating based on internal temperatures, and outputs the calculated fan speed to the fans in same group respectively. The fans in the same group run according to the received fan speed. A rack management controller (RMC) in the rack obtains the fan speed outputted by a server in one of the several groups, and calculates a fan speed compensating value based on the obtained fan speed. The RMC then outputs the fan speed compensating value to fans in neighboring groups to make it to run according to the fan speed compensating value.

### TECHNICAL FIELD

The present invention relates to racks and more particularly relates to racks with fan speed compensation.

### BACKGROUND

Usually, a server rack may contain multiple server slots for installing multiple servers. In addition, a fan wall may be installed behind the server rack. By operating the fan wall, heat generated when the multiple servers operate may be dissipated output the server rack to achieve heat dissipation.

The fan wall has multiple fans and the multiple fans respectively face locations for installing servers so that the multiple fans may carry heat of the multiple servers outside the server rack.

However, the multiple servers and corresponding fans do not contact to each other but have a gap therebetween. Therefore, the heat of the multiple servers runs inside the server rack via such gap, instead of all being dissipated outside the server rack by the multiple fans.

In addition, because there is such gap between the multiple servers and the fans, when the multiple fans operate, in addition to pump the heat of front servers outside the server rack, upper and bottom cool air is also pumped outside the server rack. Such arrangement causes overall efficiency loss of heat dissipation of the server rack.

### SUMMARY OF INVENTION

A major objective of the present invention is to provide a rack with fan speed compensation and a fan speed compensation method thereof so that when fans in the rack operates to perform heat dissipation, fans in a neighbor group are also controlled by providing fan speed compensation.

To achieve the aforementioned objective, the multiple servers and multiple fans in the rack are grouped into multiple groups. Each server respectively detects its temperature condition, and calculates a necessary fan speed to be sent to the fans in the same group so that the fans in the same group operate according to the necessary fan speed. A rack management controller of the rack retrieves fan speed values from servers in a group and calculates a compensation value according to the retrieved fan speed values. Finally, the rack management controller sends the compensation value to the fans in a neighbor group so that the fans in the neighbor group operate according to the compensation value.

One technical effect of the present invention, compared with convention art, is that when servers determine the need of heat dissipation, in addition to activate fans in the same group to directly pump the heat of the servers outside the rack, fans in a neighbor group are also activated to provide compensation fan speed to pump out heat running inside the rack outside the rack. As such, the rack of the present invention that uses the fan speed compensation method of the present invention provides better heat dissipation effect than racks that only rely on fans in the same group.

### BRIEF DESCRIPTION OF DRAWING

FIG. 1 is a perspective diagram of a rack of a first embodiment according to the present invention;

FIG. 2 is a side view diagram of the rack of the first embodiment according to the present invention;

FIG. 3 is a server connection diagram of the first embodiment according to the present invention;

FIG. 4 is a fan connection diagram of the first embodiment according to the present invention;

FIG. 5 is fan connection diagram of a second embodiment according to the present invention;

FIG. 6 is a control flowchart of the first embodiment according to the present invention;

FIG. 7 is a compensation flowchart of the first embodiment according to the present invention; and

FIG. 8 is a fan speed comparison flowchart of the first embodiment according to the present invention.

### DETAILED DESCRIPTION

A preferred embodiment of the present invention with associated drawings are provided as follows.

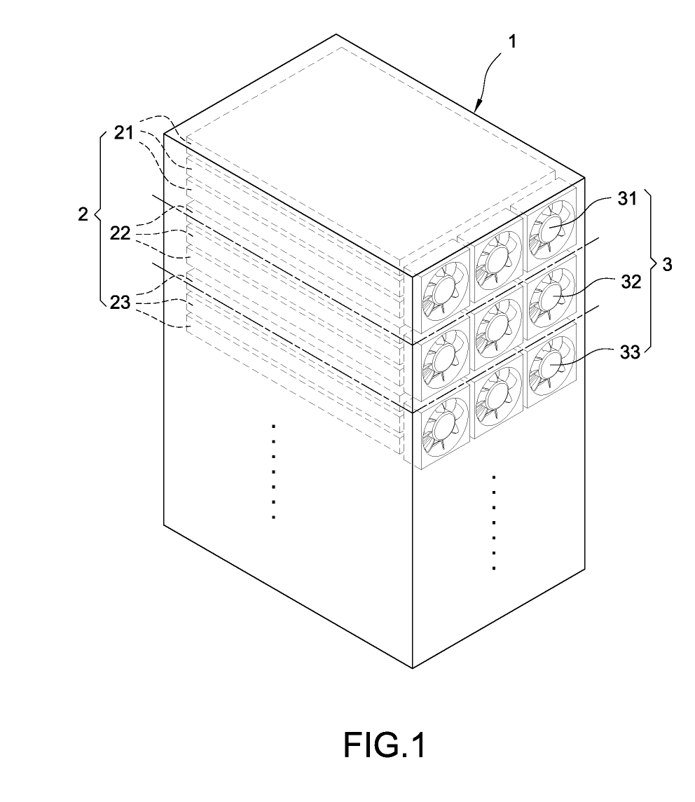

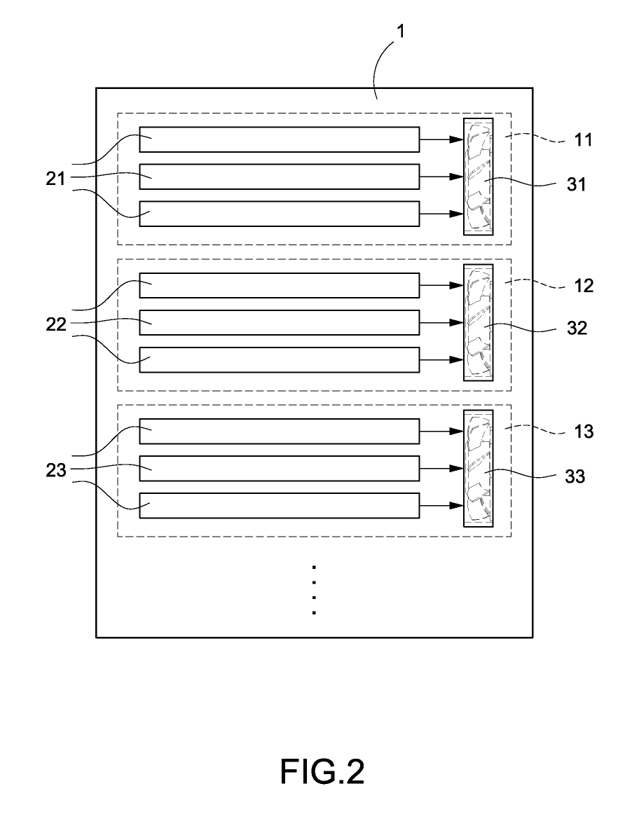

Please refer to FIG. 1 and FIG. 2, which are perspective diagram and side view diagram of a rack of the first embodiment according to the present invention. The present invention provides a rack with fan speed compensation function (hereinafter as the rack 1). The rack 1 has multiple server slots for installing multiple servers 2. A fan wall is disposed behind the rack 1 and the fan wall is composed of multiple fans 3.

In the invention, the rack 1 divides the multiple servers 2 and the multiple fans 3 into multiple groups, e.g. a first group 11, a second group 12 and a third group 13 in FIG. 2. Please be noted that such arrangement is not a limitation to the invention scope. The groups 11-13 respectively include the multiple servers 2 and the multiple fans 3. The multiple fans 3 are respectively disposed right behind the multiple servers 2 in the same group. As such, when the fans 3 operate, heat generated by the multiple servers 2 in the same group is pumped outside the rack 1.

In the embodiment of FIG. 2, the first group 11 includes a first group of servers 21 and a first group of fans 31 disposed right behind the first group of servers 21. The second group 12 includes a second group of servers 22 and a second group of fans 32 disposed right behind the second group of servers 22. The third group 13 includes a third group of servers 23 and a third group of fans 33 disposed right behind the third group of servers 23 and so forth.

Take the first group 11 as an example. When one from the first group of servers 21 determines there is a need for heat dissipation, a control instruction is sent to the first group of fans 31 in the same group (the first group 11 in this example). The first group of fans 31 operate according to the control instruction to achieve heat dissipation for the first group of servers 21. Specifically, the control instruction may include a fan speed necessary for the first group of servers 21 and the first group of serves 21 mainly sends the control instruction to a fan controller (not shown) in the fan wall. As such, the fan controller controls the first group of fans 31 so that the first group of fans 31 operate according to the fan speed recorded in the control instruction to satisfy the heat dissipation needed for the first group of servers 21.

As mentioned above, under normal operation, the multiple servers 2 only control the multiple fans 3 in the same group, but not able to control the fans 3 in other groups.

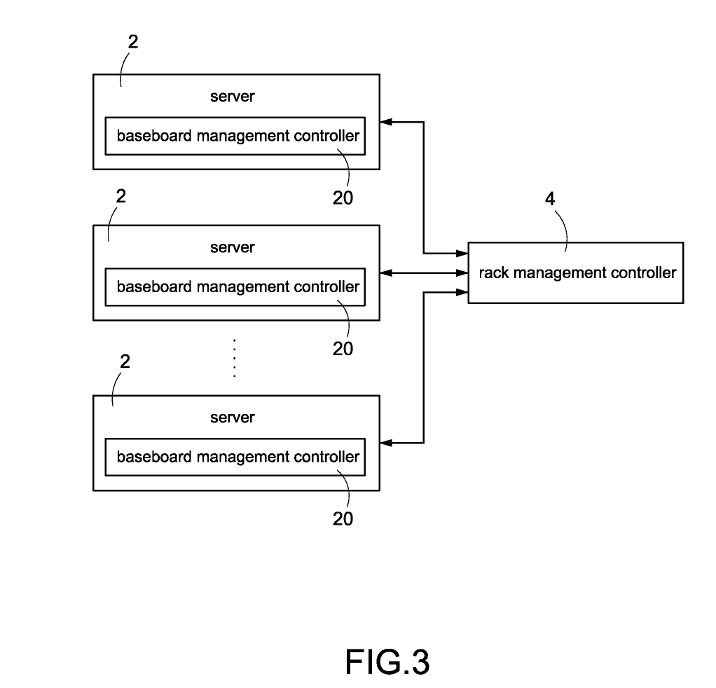

Please refer to FIG. 3, which is a server connection diagram of a first embodiment according to the present invention. As illustrated in FIG. 3, the rack 1 further includes a rack management controller (RMC) 4 for connecting to all servers 2 in the rack 1. Specifically, the multiple servers 2 respectively have baseboard management controllers (BMC). The RMC 4 is connected to and communicates with the multiple BMCs 21 respectively for collecting data of the multiple servers 2 and sending instructions to the servers 2.

When the servers 2 need heat dissipation, the internal BMCs 20 are mainly used for generating and sending the control instructions. Because the RMC 4 may communicate with these BMCs 20, the RMC 4 knows which BMC 20 sends the control instruction and also knows the content of the control instruction, e.g. the fan speed. In the present invention, the rack 1 uses the RMC 4 to perform fan speed compensation and the RMC 4 calculates necessary fan speed compensation value according to the content of the control instructions.

Specifically, by reference to the calculated fan speed, the RMC 4 controls the fans in a neighbor group of the server 2 that sends the control instructions to operate. Take the embodiment in FIG. 2, if any of the second group of servers 22 sends the control instructions, the RMC 4 sends the calculated fan speed to the first group of fans 31 in the first group 11 and the third group of fans 33 in the third group 13. The first group of fans 31 and the third group of fans 33 operate to perform compensated heat dissipation for the second group of servers 22.

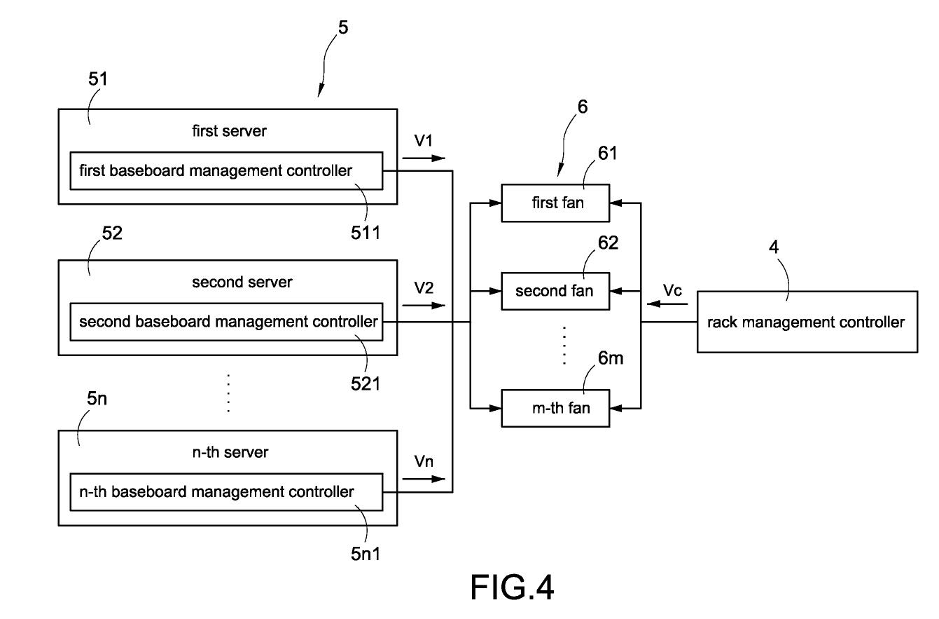

Please refer to FIG. 4, which is a fan connection diagram of the first embodiment according to the present invention. FIG. 4 discloses a server group 5 and a fan group 6 in the same group. The server group 5 is composed of n servers, i.e. a first server 51, a second server 52 to a n-th server 5n. The fan group 6 is disposed right behind the server group 5 and is composed of m fans, i.e. a first fan 61, a second fan 62 to m-th fan 6m.

As illustrated in FIG. 4, when the first server 51 determines a need for heat dissipation, a first baseboard management controller 511 of the first server 51 is used for calculating and sending a first fan speed output value V1 to the multiple fans 61-6m. When the second server 52 determines a need for heat dissipation, a second baseboard management controller 511 of the second server 52 is used for calculating and sending a second fan speed output value V2 to the multiple fans 61-6m. When the n-th server 5n determines a need for heat dissipation, a n-th baseboard management controller 5n1 of the n-th server 5n is used for calculating and sending a n-th fan speed output value Vn to the multiple fans 61-6m and so forth.

When the multiple fans 61-6m and the multiple servers 51-5n are in the same group, the multiple fans 61-6m operate according to the fan speed output values V1-Vn for performing heat dissipation of the multiple servers 51-5n in the same group so as to decrease the temperature of the multiple servers 51-5n down to a safety temperature range. Meanwhile, the multiple fans 61-6m receive a fan compensation value Vc from the RMC 4. The fan speed compensation value Vc is generated by the RMC 4 for performing heat dissipation compensation of servers in a neighbor group beside the server group 5. To perform heat dissipation compensation for servers in the neighbor group, the multiple fans 61-6m operate according to the fan compensation value Vc when receiving the fan speed compensation value Vc from the RMC 4.

In another embodiment, the rack 1 further includes multiple fan speed comparators 7 respectively connected to the multiple servers 2 and the multiple fans 3 in the same group, and connected to the RMC 4. The major effect of the fan speed comparators 7 is to ensure the fans 3 to operate in a maximum fan speed.

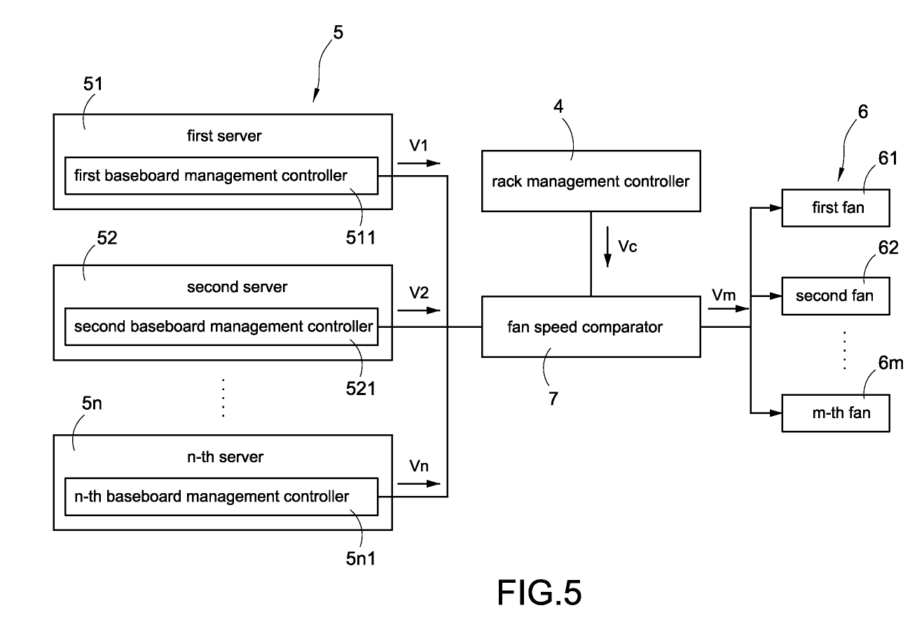

Please refer to FIG. 5, which is a fan connection diagram of the second embodiment according to the present invention. Compared with the embodiment illustrated in FIG. 4, the embodiment in FIG. 5 further includes the aforementioned fan speed comparators 7. The fan speed comparator 7 is connected to all servers 51-5n in the server group 5, all fans 61-6m in the fan group 6 and the RMC 4. When the multiple servers 51-5n determines a need of heat dissipation and calculate respectively the first fan speed output value V1, the second fan speed output value V2 to the n-th fan speed output value Vn, the baseboard management controllers 511, 521 to 5n1 are used for sending these values to the fan speed comparator 7. The fan speed comparator 7 compares these fan speed output values V1-Vn and selects the maximum fan speed output value as an ascertain fan speed value Vm and outputs the ascertain fan speed value Vm to the fan group 6. As such, the fans 61-6m operate according to the ascertain fan speed value Vm to satisfy the heat dissipation need of the multiple servers 51-5n.

When the fan group 6 operates, the RMC 4 calculates and generates a fan speed compensation value Vc for the group for controlling the fans in a neighbor group to perform compensation. If another server group (not shown) neighbor to the server group 5 also performs heat dissipation, the RMC 4 also calculates and generates a fan speed compensation value Vc and sends the value to the fan speed comparator 7. In such case, the fan speed comparator 7 compares the fan speed output values V1-Vn and the fan speed compensation value Vc and selects the maximum therein as the ascertain fan speed value Vm.

For example, if the first fan speed output value V1 is 50%, the second fan speed output value V2 is 30% and the fan speed output value Vn is 40%, the fan speed comparator 7 compares these values and determines taking the first fan speed output value V1 as the ascertain fan speed value Vm and instructs the fans 61-6m to operate in 50% fan speed. In another example when the fan speed comparator 7 receives the fan speed compensation value Vc from the RMC 4 at the same time and the fan speed compensation value Vc is 75%, the fan speed comparator 7 compares these values and changes the ascertain fan speed value Vm as the fan speed compensation value Vc and instructs the fans 61-6m to operate in 75% fan speed. As such, the fans 61-6m are able to perform heat dissipation for the servers 51-5n in the same group and also perform heat dissipation compensation for servers in a neighbor group.

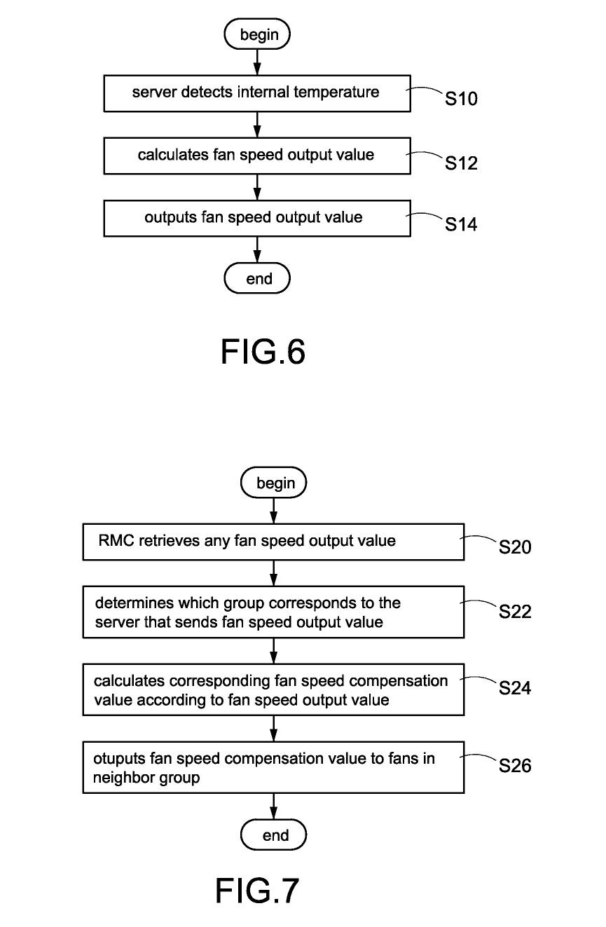

Please refer to FIG. 6, which is a control flowchart of the first embodiment according to the present invention. Please also refer to the rack 1 illustrated in FIG. 1 and FIG. 2 for the following explanation of FIG. 6. First, each server 2 respectively uses the baseboard management controller 20 to detect the internal temperature (step S10). The temperature in this embodiment may refer to temperature of motherboard, CPU, memory, hard disk or any other temperature.

When the baseboard management controllers 20 determine heat dissipation needs, they respectively calculate and generate the aforementioned fan speed output values (step S12). In this embodiment, these baseboard management controllers 20 record a fan speed mapping table. By looking up the fan speed mapping table, the current temperature is converted to a fan speed of the fans 3 in the same group. In another embodiment, these baseboard management controllers 20 may respectively have an algorithm for calculating necessary fan speeds according to the detected temperatures by the algorithms. These configurations are not limitation of the invention scope.

After the step S12, these baseboard management controllers 20 respectively output the fan speed output values (step S14). In this embodiment, these baseboard management controllers 20 output the fan speed output values to the fans 3 (or the fan controller) in the same group. In another embodiment, these baseboard management controllers 20 output the fan speed output values to the fan speed comparator 7 in the same group. These configurations are not limitation of the invention scope.

Please refer to FIG. 7, which is a compensation flowchart of the first embodiment according to the present invention. Firstly, the RMC 4 in the rack 1 retrieves any of the plurality of fan speed output values (step S20). The RMC 4 may directly retrieve the fan speed output value directly from the servers 2 or from the fans 3. These configurations are not limitation of the invention scope.

The RMC 4 first determines which group corresponds to the server that outputs the fan speed output value (step S22) and then calculates the fan speed compensation value Vc according to the fan speed output value. In this embodiment, the RMC 4 may record another fan speed mapping table. By looking up the table, the RMC 4 converts the fan speed output value to the fan speed compensation value Vc. In another embodiment, the RMC 4 may have another algorithm for calculating necessary fan speed compensation value Vc in real time by this algorithm. These configurations are not limitation of the invention scope.

Finally, the RMC 4 outputs the fan speed compensation value Vc to multiple fans 3 in a neighbor group (step S26) so that the multiple fans 3 in the neighbor group operate according to the fan speed compensation value Vc to perform heat dissipation compensation. In another embodiment, the RMC 4 outputs the fan speed compensation value Vc to the fan speed comparator 7 in a neighbor group. These configurations are not limitation of the invention scope.

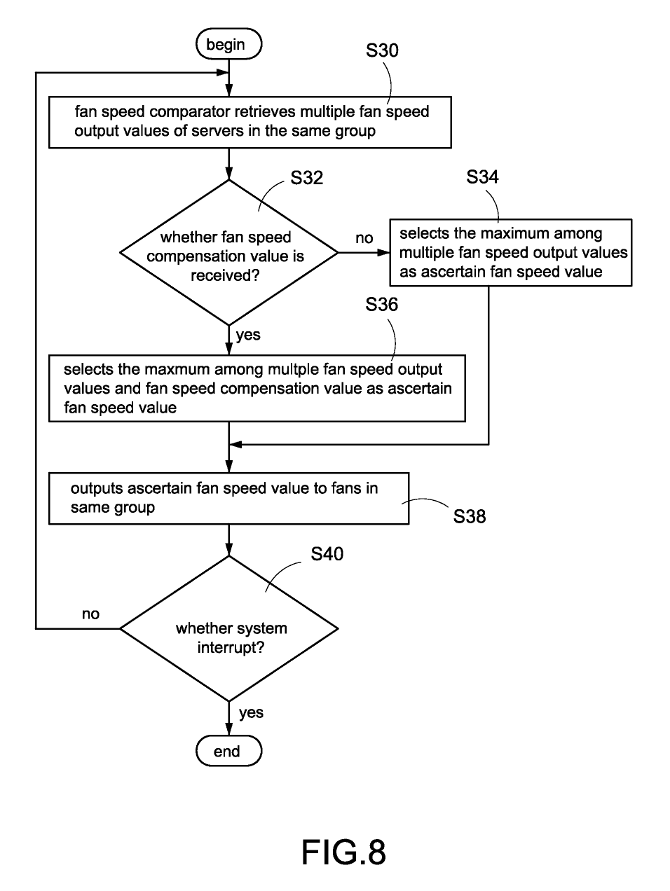

Please refer to FIG. 8, which is a fan speed comparison flowchart for the first embodiment according to the present invention. The flowchart in FIG. 8 is used to explain the steps for the fan speed comparator 7 to generate the ascertain fan speed value Vm. First, the fan speed comparator 7 retrieves multiple fan speed output values from the multiple servers 2 in the same group (step S30). Meanwhile, it is determined whether the fan speed compensation value Vc from the RMC 4 is received (step S32).

If the fan speed compensation value Vc is not received, the fan speed comparator 7 selects the maximum value among the multiple fan speed output values as the ascertain fan speed value Vm (step S34). Otherwise, if the fan speed compensation value Vc is received, the fan speed comparator 7 selects the maximum value among the multiple fan speed output values and the fan speed compensation value Vc as the ascertain fan speed value Vm (step S36). Finally, the fan speed comparator 7 outputs the ascertain fan speed value Vm to the multiple fans in the same group (step S38) so that the multiple fans operate according to the ascertain fan speed value Vm.

After these steps, the fan speed comparator 7 determines whether the system in the rack 1 is interrupted (step S40). Before the system is interrupted, the steps S30 to S38 are performed repeatedly to control the fans 3 to perform heat dissipation for the multiple servers in the same group and also perform heat dissipation compensation for multiple servers in a neighbor group.

The foregoing descriptions of embodiments of the present invention have been presented only for purposes of illustration and description. They are not intended to be exhaustive or to limit the present invention to the forms disclosed. Accordingly, many modifications and variations will be apparent to practitioners skilled in the art. Additionally, the above disclosure is not intended to limit the present invention. The scope of the present invention is defined by the appended claims.

What is claimed is:

1. A rack having fan speed compensation function, comprising:
a plurality of servers respectively calculating fan speed output values according to internal temperature;
a plurality of fans disposed behind the plurality of servers and grouped into a same group of the plurality of servers; and
a rack management controller connected to the plurality of servers and the plurality of fans to retrieve the fan speed output values for calculating a fan speed compensation value accordingly,
wherein the plurality of fans operate according to the fan speed output values sent by the plurality of servers in the same group, and the rack management controller sends the fan speed compensation value to a plurality of fans in a neighbor group so that the plurality of the fans in the neighbor group operate according to the fan speed compensation value.

2. The rack of claim 1, wherein each of the plurality of servers respectively has a baseboard management controller, and the plurality of servers respectively communicate with the rack management controller, detect internal temperatures and calculate the fan speed output values via the baseboard controllers.

3. The rack of claim 2, wherein each of the baseboard management controllers respectively records a fan speed mapping table, and the baseboard management controllers respectively convert internal temperature into the fan speed output values according to the fan speed mapping table.

4. The rack of claim 2, wherein the rack management controller records a fan speed mapping table, and the rack management controller converts the fan speed output values into the fan speed compensation value according to the fan speed mapping table.

5. The rack of claim 2, further comprising a fan speed comparator connected to the plurality of servers and the plurality of fans in the same group, wherein the fan speed comparator receives the fan speed output values and selects a maximum value from the fan speed output values as an ascertain fan speed value to be outputted to the plurality of fans and the plurality of fans operate according to the ascertain fan speed value.

6. The rack of claim 5, wherein the fan speed comparator further receives another fan speed compensation value sent from the rack management controller, wherein said another fan speed compensation value is calculated when the rack management controller performs heat dissipation compensation for a plurality of servers in a neighbor group, and wherein the fan speed comparator selects a maximum value among the fan speed output values and said another fan speed compensation value as the fan speed ascertain value to be outputted to the plurality of fans.

7. A fan speed compensation method used in a rack, comprising:
a) retrieving a plurality of fan speed output values sent from a plurality of servers, wherein a plurality of fans in a same group as the plurality of servers operate according to the plurality of fan speed output values;
b) calculating a fan speed compensation value according to the plurality of fan speed output values; and
c) transmitting the fan speed compensation value to a plurality of fans in a neighbor group so that the plurality of fans in the neighbor group operate according to the fan speed compensation value.

8. The fan speed compensation method of claim 7, further comprising steps before the step a) as:
a01) detecting internal temperature respectively by the plurality of servers;
a02) calculating the plurality of fan speed output values according to the internal temperature; and
a03) transmitting the plurality of fan speed output values to the plurality of fans in the same group.

9. The fan speed compensation method of claim 7, wherein the rack has a fan speed comparator connected to the plurality of servers and the plurality of fans in the same group, and wherein the step a) comprises:
a11) retrieving the plurality of fan speed output values;
a12) comparing the plurality of fan speed output values and selecting a maximum value among the plurality of fan speed output values as an ascertain fan speed value; and
a13) outputting the ascertain fan speed value to the plurality of fans in the same group, wherein the plurality of fans in the same group operate according to the ascertain fan speed value.

10. The fan speed compensation method of claim 7, wherein the rack has a fan speed comparator connected to the plurality of servers and the plurality of fans in the same group, and wherein the step a) comprises:
a21) retrieving the plurality of fan speed output values;
a22) retrieving another fan speed compensation value, wherein said another fan speed compensation value is calculated for heat dissipation for the plurality of servers in a neighbor group;
a23) comparing the plurality of fan speed output values and said another fan speed compensation value and selecting a maximum value among the plurality of fan speed output values and said another fan speed compensation value as an ascertain fan speed value; and
a24) outputting the ascertain fan speed value to the plurality of fans in the same group, wherein the plurality of fans in the same group operate according to the ascertain fan speed value.
